(19) United States
(12) Patent Application Publication
(10) Pub. No.: US 2025/0093481 A1
(43) Pub. Date: Mar. 20, 2025

(54) LIGHT SOURCE DRIVING DEVICE, LIGHT EMITTING DEVICE, AND DISTANCE MEASURING DEVICE

(71) Applicant: SONY SEMICONDUCTOR SOLUTIONS CORPORATION, KANAGAWA (JP)

(72) Inventors: TAKAHIRO KITA, KUMAMOTO (JP); KOUJI MORI, KUMAMOTO (JP); HAYATO KAMIZURU, KUMAMOTO (JP); KATSUHISA DAIO, KUMAMOTO (JP)

(21) Appl. No.: 18/290,822

(22) PCT Filed: Mar. 25, 2022
(86) PCT No.: PCT/JP2022/014728

§ 371 Date: Jan. 22, 2024

(30) Foreign Application Priority Data
Aug. 5, 2021 (JP) 2021-129060

(51) Int. Cl. G01S 7/497; G01S 17/08

(52) U.S. Cl. CPC G01S 7/497; G01S 17/08

(57) ABSTRACT

Protection capability at the time of abnormality of a light source is improved. A light source driving device includes an emission unit, a light receiving unit, an abnormality detection unit, a light source control unit, and an emission control unit. The emission unit collects and emits light from the light source. The light receiving unit receives light from the light source via the emission unit. The abnormality detection unit detects an abnormality of light emitted from the emission unit based on the received light. The light source control unit controls light emission of the light source, and stops the light emission of the light source when an abnormality is detected. The emission control unit controls light collection of the emission unit, and stops the light collection of the emission unit when an abnormality is detected.

### FIELD

The present disclosure relates to a light source driving device, a light emitting device, and a distance measuring device.

### BACKGROUND

A distance measuring device is used in a distance measuring device that measures a distance to an object. The distance measuring device applies light to the object, and detects reflected light from the object. The distance measuring device measures a distance by measuring a time during which light travels between the distance measuring device and the object. In such a distance measuring device, a light source that applies light to the object is disposed. This light source needs to apply light in a light amount (intensity) supporting a distance measurement range. A light source including a laser diode that generates laser light as a light emitting element is used as a light source of a distance measuring device supporting a relatively large distance measurement range.

Laser light having a high energy density is harmful to a human body. Thus, there is proposed a light source driving device that performs control in which an abnormality of a light emitting element is detected and light emission is stopped (e.g., see Patent Literature 1). The light source driving device includes a light source control unit and a light receiving unit. The light source control unit controls a light source of a laser diode. The light receiving unit receives light from the light source. Then, the light source driving device stops control of light emission of the light source in the light source control unit when the light receiving unit detects an abnormality of the laser diode.

### CITATION LIST

### Patent Literature

Patent Literature 1: JP 2020-047874 A

### SUMMARY

### Technical Problem

Unfortunately, the above-described technique provides insufficient protection at the time of abnormality of a light source. For example, a conventional technique cannot handle a case where an abnormality that cannot be handled by the control of a light source control unit occurs, for example, a case where an abnormal current flows through a laser diode due to breakage of a semiconductor element for control of the laser diode and the like. In this case, it is necessary to perform processing of, for example, stopping power supply to the laser diode with an application processor or the like that controls a light source driving device. Unfortunately, this processing takes time, which leads to insufficient protection.

Therefore, the present disclosure proposes a light source driving device, a light emitting device, and a distance measuring device that improve protection capability at the time of abnormality of a light source.

### Solution to Problem

A light source driving device according to the present disclosure includes: an emission unit that collects and emits light from a light source; a light receiving unit that receives light from the light source via the emission unit; an abnormality detection unit that detects an abnormality of light emitted from the emission unit based on the light that has been received; a light source control unit that controls light emission of the light source and stops the light emission of the light source when the abnormality of light is detected; and an emission control unit that controls light collection of the emission unit and stops the light collection of the emission unit when the abnormality of light is detected.

### BRIEF DESCRIPTION OF DRAWINGS

FIG. 1 illustrates a configuration example of a light emitting device according to an embodiment of the present disclosure.

FIG. 2 is a block diagram illustrating a configuration example of the light emitting device according to the embodiment of the present disclosure.

FIG. 3 illustrates a configuration example of a light source driving circuit according to the embodiment of the present disclosure.

FIG. 4 illustrates a configuration example of an emission unit according to the embodiment of the present disclosure.

FIG. 5 illustrates a configuration example of a distance measuring device to which the technology according to the present disclosure can be applied.

### DESCRIPTION OF EMBODIMENTS

An embodiment of the present disclosure will be described in detail below with reference to the drawings. The description will be given in the following order. Note that, in the following embodiment, the same reference signs are attached to the same parts to omit duplicate description.
1. Embodiment
2. Example of Application to Distance Measuring Device

### 1. Embodiment

### Configuration of Light Emitting Device

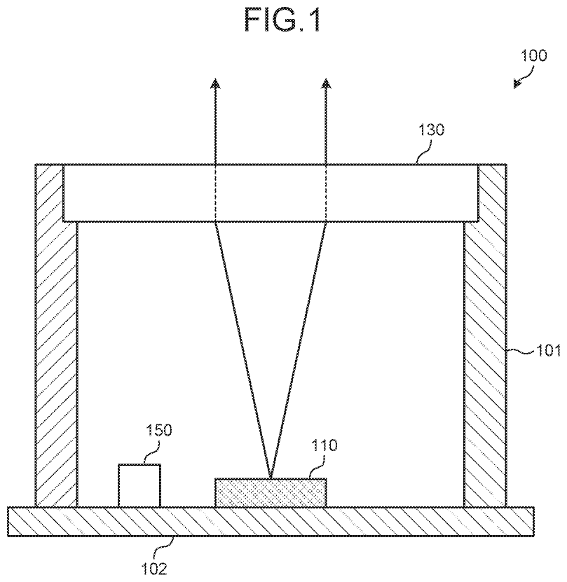

FIG. 1 illustrates a configuration example of a light emitting device according to the embodiment of the present disclosure. The figure is a cross-sectional view illustrating a configuration example of a light emitting device 100. The light emitting device 100 includes a light source 110, and emits light. The light emitting device 100 in the figure includes a substrate 102 and a housing 101. The light source 110 is mounted on the substrate 102. The housing 101 surrounds the light source 110. The housing 101 is made of metal and the like. The housing 101 protects the light source 110, and blocks light from the light source 110. An emission unit 130 is disposed above the housing 101. The emission unit 130 collects light from the light source 110. Arrows in the figure indicate light emitted from the light source 110 and collected by the emission unit 130. An example in which the emission unit 130 in the figure collects light in a dot shape and emits the light is illustrated. A light receiving unit 150 is further disposed on the substrate 102 in the vicinity of the light source 110 in the figure. The light receiving unit 150 detects a beam of light reflected by the emission unit 130 among beams of light from the light source 110.

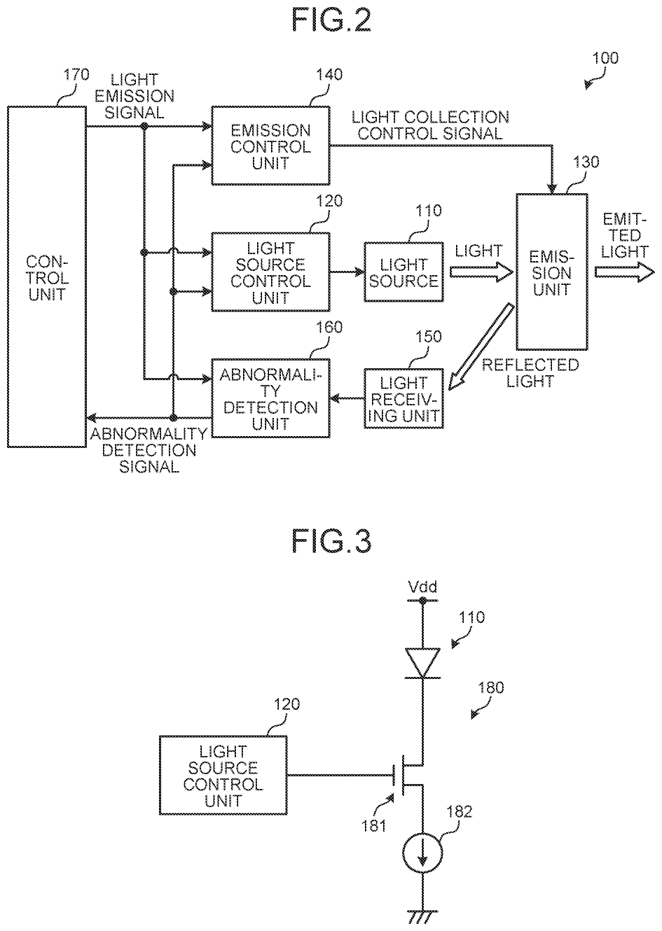

FIG. 2 is a block diagram illustrating the configuration example of the light emitting device according to the embodiment of the present disclosure. The figure is a block diagram illustrating a configuration example of the light emitting device 100. The light emitting device 100 includes the light source 110, a light source control unit 120, the emission unit 130, an emission control unit 140, the light receiving unit 150, an abnormality detection unit 160, and a control unit 170. Note that the light source control unit 120, the emission unit 130, the emission control unit 140, the light receiving unit 150, the abnormality detection unit 160, and the control unit 170 in the figure are examples of a light source driving device described in the claims.

The light source 110 applies light. A laser diode that applies infrared light can be used for the light source 110.

The light source control unit 120 controls light emission and non-light emission of the light source 110. The light source control unit 120 can control the light emission and the non-light emission of the light source 110 by, for example, outputting a signal for controlling a light source driving circuit (not illustrated) that drives the light source 110. The light source control unit 120 in the figure controls the light source 110 under the control of the control unit 170. Note that, when the abnormality detection unit 160 detects an abnormality, the light source control unit 120 further performs processing of stopping light emission of the light source 110. Light emission of the light source 110 can be stopped at the time of abnormality by the processing.

The emission unit 130 collects light from the light source 110 as described above. The emission unit 130 in the figure collects light under the control of the emission control unit 140. Specifically, the emission unit 130 can switch between a mode of collecting light and a mode of non-light collection. The emission unit 130 in the figure can switch the mode based on a control signal from the emission control unit 140. For example, a mode in which light is collected in a dot shape (spot shape) and emitted as illustrated in FIG. 1 can be applied to the light collection mode. This enables light to be applied to a relatively distant object. In contrast, for example, a mode in which light is diffused and emitted can be applied to the non-light collection mode. Since diffused light has a low energy density, an influence can be reduced even if the diffused light is applied to a human body.

The emission control unit 140 controls light collection in the emission unit 130. The emission control unit 140 controls light collection by outputting a control signal (light collection control signal in figure) for controlling light collection of the emission unit 130. The emission control unit 140 controls the emission unit 130 to the light collection mode under the control of the control unit 170. In contrast, when the abnormality detection unit 160 detects an abnormality, the emission control unit 140 causes the emission unit 130 to transition to the non-light collection mode. This can prevent emission of light (dotted light) collected at the time of abnormality.

The control unit 170 controls the entire light emitting device 100. The control unit 170 controls the light source control unit 120 by outputting a light emission signal for causing the light source 110 to emit light to the light source control unit 120 based on an instruction from a higher-level device. Specifically, when the control unit 170 outputs a light emission signal, the light source control unit 120 causes the light source 110 to emit light. When the output of the light emission signal from the control unit 170 is stopped, the light source control unit 120 stops the light emission of the light source 110. Furthermore, the light emission signal is also output to the emission control unit 140. When the control unit 170 outputs a light emission signal, the emission control unit 140 outputs a light collection control signal to the emission unit 130, and causes the emission unit 130 to collect light. When the output of the light emission signal from the control unit 170 is stopped, the emission control unit 140 stops the output of the light collection control signal. Furthermore, the light emission signal is also output to the abnormality detection unit 160.

As described above, the light receiving unit 150 detects a beam of light reflected by the emission unit 130 (reflected light in figure) among beams of light from the light source 110. The light receiving unit 150 outputs a signal corresponding to the reflected light to the abnormality detection unit 160.

The abnormality detection unit 160 detects an abnormality of the light source 110 and the like based on a signal from the light receiving unit 150. When detecting an abnormality, the abnormality detection unit 160 outputs an abnormality detection signal to the control unit 170, the light source control unit 120, and the emission control unit 140. The control unit 170 and the like can be notified of detection of an abnormality by the output of the abnormality detection signal.

For example, the abnormality detection unit 160 can detect, as an abnormal state, a state in which excessive reflected light is emitted from the emission unit 130. For example, the abnormality detection unit 160 can detect, as an abnormal state, a case where output of the light source 110 is increased more than expected and a signal from the light receiving unit 150 exceeds a predetermined threshold. Furthermore, for example, the abnormality detection unit 160 can detect, as an abnormal state, a case where a signal from the light receiving unit 150 exceeds a predetermined threshold in a state in which the control unit 170 has output no light emission signal. In this case, a cause such as breakage of the light source driving circuit of the light source 110 is assumed.

Furthermore, for example, the abnormality detection unit 160 can detect, as an abnormal state, a case where a signal from the light receiving unit 150 is less than a predetermined threshold in a state in which the control unit 170 has output a light emission signal. In this case, causes such as breakage of the emission unit 130 and breakage of the light source 110 are assumed.

When detecting such an abnormal state, the abnormality detection unit 160 generates an abnormality detection signal, and outputs the abnormality detection signal to the control unit 170. The control unit 170 to which the abnormality detection signal has been input performs control of stopping the output of a light emission signal. When the input of an abnormality detection signal continues even after the output of a light emission signal is stopped, the control unit 170 determines that a driving circuit that drives the light source 110 has been broken, and performs processing of stopping power supply to the light source 110, for example. This can stop light emission of the light source 110 at the time of abnormality.

Since the processing of stopping light emission of the light source 110 via the control unit 170 takes time, however, the abnormality detection unit 160 also outputs abnormality detection signals to the light source control unit 120 and the emission control unit 140 as described above. This enables the light source control unit 120 to perform processing of stopping light emission (transition to non-light emission) of the light source 110 at the time of abnormality, and enables the emission control unit 140 to perform processing of stopping light collection of the emission unit 130 at the time of abnormality. Since these pieces of processing do not pass through the control unit 170, the pieces of processing can be performed at high speed. Furthermore, the light source control unit 120 and the emission control unit 140 doubly perform protection at the time of abnormality, so that protection capability can be improved.

### Light Source Driving Circuit

FIG. 3 illustrates a configuration example of the light source driving circuit according to the embodiment of the present disclosure. The figure is a circuit diagram illustrating a configuration example of a light source driving circuit 180. Note that the figure illustrates the light source 110 and the light source control unit 120. Furthermore, a power supply line Vdd for supplying power to the light source 110 is arranged in the circuit of the figure.

The light source driving circuit 180 includes a MOS transistor 181 and a constant current circuit 182. An n-channel MOS transistor can be used for the MOS transistor. Furthermore, the constant current circuit 182 supplies suction driving current to the light source 110. An anode of the light source 110 is connected to the power supply line Vdd. A cathode thereof is connected to a drain of the MOS transistor 181. A source of the MOS transistor 181 is grounded via the constant current circuit 182. A gate thereof is connected to the output of the light source control unit 120.

When an ON signal from the light source control unit 120 is applied to the gate of the MOS transistor 181, the MOS transistor 181 is conducted, and a current from the constant current circuit 182 flows to the light source 110. This causes the light source 110 to emit light. In the light source driving circuit 180 in the figure, when the MOS transistor 181 or the constant current circuit 182 is broken in a short-circuit state, a current constantly flows through the light source 110. Even when such an abnormal state is detected, the emission control unit 140 can stop the light collection of the emission unit 130. The control unit 170 can prevent emission of dotted laser light before the power supply to the power supply line Vdd is stopped.

### Configuration of Emission Unit 130

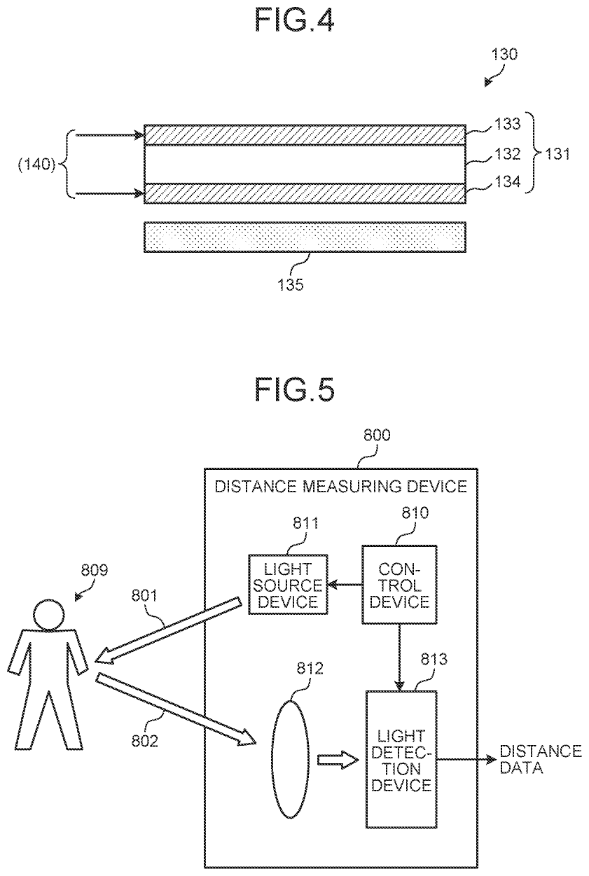

FIG. 4 illustrates a configuration example of an emission unit according to the embodiment of the present disclosure. The figure is a cross-sectional view illustrating a configuration example of the emission unit 130. The emission unit 130 in the figure includes a liquid crystal shutter 131 and a diffractive optical element 135. The diffractive optical element 135 converts laser light into light in a predetermined pattern by diffraction. The diffractive optical element 135 in the figure converts laser light into dotted light. The liquid crystal shutter 131 controls transmission of light from the diffractive optical element 135. The liquid crystal shutter 131 can adopt a configuration in which a liquid crystal unit 132 is sandwiched between transparent electrodes 133 and 134.

When a light collection control signal from the emission control unit 140 is applied to the transparent electrodes 133 and 134, liquid crystal of the liquid crystal unit 132 is aligned in a predetermined direction to have an increased transmittance and become transparent. This enables light from the diffractive optical element 135 to be transmitted. In contrast, when the application of a light collection control signal from the emission control unit 140 to the transparent electrodes 133 and 134 is stopped, the alignment of the liquid crystal in the liquid crystal unit 132 is stopped. This causes light from the diffractive optical element 135 to be diffused by the liquid crystal shutter 131 and converted into diffused light. As described above, the emission unit 130 can emit collected light in accordance with the light collection control signal from the emission control unit 140. Furthermore, attenuation can be made by diffusing emitted light at the time of abnormality.

Note that the configuration of the emission unit 130 is not limited to this example. For example, a configuration including a shutter mechanism that blocks emitted light instead of the liquid crystal shutter 131 can be adopted.

As described above, the light emitting device 100 of the embodiment of the present disclosure detects an abnormality of the light source 110 with the abnormality detection unit 160, and outputs an abnormality detection signal. The light source control unit 120 stops light emission of the light source 110 while the emission control unit 140 stops light collection of the emission unit 130 based on the abnormality detection signal. This can prevent emission of collected light at the time of abnormality, and can protect a human body and the like. Protection capability can be improved by providing double protection means of the light source control unit 120 and the emission control unit 140.

### 2. Example of Application to Distance Measuring Device

The light emitting device 100 of the above-described embodiment can be applied to various products. An example in which the light emitting device 100 is applied to a distance measuring device will be described.

FIG. 5 illustrates a configuration example of a distance measuring device to which the technology according to the present disclosure can be applied. The figure is a block diagram illustrating a configuration example of a distance measuring device 800. The distance measuring device 800 includes a light detection device 813, a control device 810, a light source device 811, and an imaging lens 812. The distance measuring device 800 measures a distance to an object. The figure further illustrates an object 809.

The light source device 811 emits light. The light source device 811 applies emitted light 801 to the object 809 at the time of measuring a distance. For example, a light emitting diode that emits infrared light can be used for the light source device 811.

The imaging lens 812 collects light from the object 809 to the light detection device 813. The imaging lens 812 in the figure collects reflected light 802, which is obtained by the emitted light 801 being reflected by the object 809, to the light detection device 813.

The light detection device 813 detects the reflected light 802 from the object 809, and measures a distance to the object 809. The light detection device 813 includes a sensor and a processing circuit. The sensor detects the reflected light 802. The processing circuit performs distance measuring processing. In the distance measuring processing, a time from emission of the emitted light 801 performed by the light source device 811 to detection of the reflected light 802 is measured, and a distance to the object 809 is measured based on the measured time from emission of the emitted light 801 to detection of the reflected light 802. The measured distance to the object 809 is output to an external device as distance data.

The control device 810 controls the entire distance measuring device 800. At the time of measuring a distance, the control device 810 performs control in which the light source device 811 is controlled so as to emit the emitted light 801 and the light detection device 813 is controlled so as to start time measurement and measure a distance.

The light emitting device 100 in the figure can be applied to the light source device 811 in FIG. 2.

### Effects

The light source driving device includes the emission unit 130, the light receiving unit 150, the abnormality detection unit 160, the light source control unit 120, and the emission control unit 140. The emission unit 130 collects and emits light from the light source 110. The light receiving unit 150 receives light from the light source 110 via the emission unit 130. The abnormality detection unit 160 detects an abnormality of light emitted from the emission unit 130 based on the received light. The light source control unit 120 controls light emission of the light source 110, and stops the light emission of the light source 110 when an abnormality is detected. The emission control unit 140 controls light collection of the emission unit 130, and stops the light collection of the emission unit 130 when an abnormality is detected. This enables two of the light source control unit 120 and the emission control unit 140 to stop emission of collected light when an abnormality is detected.

Furthermore, the emission unit 130 may stop light collection by diffusing and emitting light from the light source 110. This can attenuate emitted light.

Furthermore, when an amount of received light exceeds a predetermined threshold, the abnormality detection unit 160 may detect an abnormality.

Furthermore, when an amount of received light is less than a predetermined threshold, the abnormality detection unit 160 may detect an abnormality.

Furthermore, a control unit that controls the light source control unit 120 and the emission control unit 140 may be further included. This enables the control unit to further perform processing at the time of abnormality.

The light emitting device 100 includes the light source 110, the emission unit 130, the light receiving unit 150, the abnormality detection unit 160, the light source control unit 120, and the emission control unit 140. The emission unit 130 collects and emits light from the light source 110. The light receiving unit 150 receives light from the light source 110 via the emission unit 130. The abnormality detection unit 160 detects an abnormality of light emitted from the emission unit 130 based on the received light. The light source control unit 120 controls light emission of the light source 110, and stops the light emission of the light source 110 when an abnormality is detected. The emission control unit 140 controls light collection of the emission unit 130, and stops the light collection of the emission unit 130 when an abnormality is detected. This enables two of the light source control unit 120 and the emission control unit 140 to stop emission of collected light when an abnormality is detected.

The distance measuring device 800 includes a light emitting device, a sensor, and a processing circuit. The light emitting device includes the light source 110, the emission unit 130, the light receiving unit 150, the abnormality detection unit 160, the light source control unit 120, and the emission control unit 140. The emission unit 130 collects and emits light from the light source 110. The light receiving unit 150 receives light from the light source 110 via the emission unit 130. The abnormality detection unit 160 detects an abnormality of light emitted from the emission unit 130 based on the received light. The light source control unit 120 controls light emission of the light source 110, and stops the light emission of the light source 110 when an abnormality is detected. The emission control unit 140 controls light collection of the emission unit 130, and stops the light collection of the emission unit 130 when an abnormality is detected. The sensor detects reflected light obtained by light emitted from the light source 110 being reflected by an object.

The processing circuit performs processing of measuring a distance to the object based on the time from the emission of light from the light source 110 to the detection of the reflected light. This enables two of the light source control unit 120 and the emission control unit 140 to stop emission of collected light when an abnormality is detected.

Note that the effects described in the present specification are merely examples and not limitations. Other effects may be obtained.

Note that the present technology can also have the configurations as follows.
(1)

A light source driving device comprising:
an emission unit that collects and emits light from a light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected.
(2)

The light source driving device according to the above (1),
wherein the emission unit stops the light collection by diffusing and emitting light from a light source.
(3)

The light source driving device according to the above (1) or (2),
wherein the abnormality detection unit detects the abnormality when an amount of the light that has been received exceeds a predetermined threshold.
(4)

The light source driving device according to the above (1) or (2),
wherein the abnormality detection unit detects the abnormality when an amount of the light that has been received is less than a predetermined threshold.
(5)

The light source driving device according to any one of the above (1) to (4), further comprising a control unit that controls the light source control unit and the emission control unit.
(6)

A light emitting device comprising:
a light source;
an emission unit that collects and emits light from the light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected.
(7)

A distance measuring device comprising:
a light emitting device including:
a light source;
an emission unit that collects and emits light from the light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected;
a sensor that detects reflected light obtained by light emitted from the light source being reflected by an object; and
a processing circuit that performs processing of measuring a distance to the object based on a time from emission of light from the light source to detection of the reflected light.

### REFERENCE SIGNS LIST

100 LIGHT EMITTING DEVICE
110 LIGHT SOURCE
120 LIGHT SOURCE CONTROL UNIT
130 EMISSION UNIT
140 EMISSION CONTROL UNIT
150 LIGHT RECEIVING UNIT
160 ABNORMALITY DETECTION UNIT
170 CONTROL UNIT
800 DISTANCE MEASURING DEVICE
811 LIGHT SOURCE DEVICE

1. A light source driving device comprising:
an emission unit that collects and emits light from a light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected.

2. The light source driving device according to claim 1,
wherein the emission unit stops the light collection by diffusing and emitting light from a light source.

3. The light source driving device according to claim 1,
wherein the abnormality detection unit detects the abnormality when an amount of the light that has been received exceeds a predetermined threshold.

4. The light source driving device according to claim 1,
wherein the abnormality detection unit detects the abnormality when an amount of the light that has been received is less than a predetermined threshold.

5. The light source driving device according to claim 1, further comprising a control unit that controls the light source control unit and the emission control unit.

6. A light emitting device comprising:
a light source;
an emission unit that collects and emits light from the light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected.

7. A distance measuring device comprising:
a light emitting device including:
a light source;
an emission unit that collects and emits light from the light source;
a light receiving unit that receives light from the light source via the emission unit;
an abnormality detection unit that detects an abnormality of light emitted from the emission unit based on the light that has been received;
a light source control unit that controls light emission of the light source and stops the light emission of the light source when the abnormality of light is detected; and
an emission control unit that controls light collection of the emission unit and stops the light collection of the emission unit when the abnormality of light is detected;
a sensor that detects reflected light obtained by light emitted from the light source being reflected by an object; and
a processing circuit that performs processing of measuring a distance to the object based on a time from emission of light from the light source to detection of the reflected light.
